(19) United States
(12) Patent Application Publication
(10) Pub. No.: US 2003/0182600 A1
(43) Pub. Date: Sep. 25, 2003

(54) System and method for analyzing buffer usage

(75) Inventors: Herbert Lyvirn Lacey III, Garner, NC (US); Robert J. Miller, Raleigh, NC (US)

Correspondence Address: HUNTON & WILLIAMS, INTELLECTUAL PROPERTY DEPARTMENT, 1900 K STREET, N.W., SUITE 1200, WASHINGTON, DC, 20006-1109, US

(73) Assignee: GlobespanVirata Incorporated, Red Bank, NJ (US)

(21) Appl. No.: 09/683,773

(22) Filed: Feb. 13, 2002

Related U.S. Application Data
(60) Provisional application No. 60/343,188, filed on Dec. 31, 2001.

(51) Int. Cl. G11C 29/00; H04B 1/74

(52) U.S. Cl. 714/42; 714/718

(57) ABSTRACT

A system and method is provided for enabling analysis of memory buffer usage. Initially, each of the buffer using system components are assigned a unique ownership tag. Next, upon buffer allocation to a particular component, the allocated buffer is tagged with the calling component's ownership tag. Once tagged, the system operates conventionally, with the calling component utilizing the buffer to perform any task it has been assigned. Following completion of its tasks(s), the calling component calls a buffer checker application which searches the buffer pool for the calling component's ownership tag. Next, upon search completion, the calling component determines whether the buffer checker has identified the calling component's ownership tag in its search. If so, a potential buffer leak is identified and a log of such occurrences is created. A system developer or administrator then periodically reviews the log for potential buffer leakage occurrences to assist is subsequent debugging and analysis.

### CROSS REFERENCE TO RELATED APPLICATIONS

This application claims the benefit of U.S. provisional patent application Serial No. 60/343,188 filed Dec. 31, 2001, the disclosure of which is incorporated herein by reference.

### BACKGROUND OF THE INVENTION

The present invention relates generally to data processing systems and, more particularly, to systems and methods for testing and debugging such systems, prior to dissemination to end users.

Prior to the production, sale, and eventual delivery of developed data processing systems and software applications to consumers, the conventional practice is to conduct extensive and comprehensive testing of the system or software in order to ensure that it will operate in accordance with the manufacturer's objectives as well as the end user's expectations. In general, such testing conventionally requires running the system or software under a wide variety of operating conditions, thereby enabling the developers to effectively force the systems into scenarios which may cause the system to operate incorrectly or crash. Once such failure occurs, the system may be analyzed with the goal of identifying the cause of the failure.

Unfortunately, the identification of system bugs and flaws is not always readily apparent, even where operating conditions have been meticulously controlled. Adding to this difficulty is the fact that in many of today's complex and multipurpose data processing systems, a finished product is often a combination of various functionalities which have been individually developed. Once the individual components are deemed ready for integration into the complete system, the combined system often suffers from additional errors and faults caused by the combination of components.

One source of potential errors and system flaws results from resource sharing between various system components. In particular, many of today's data processing systems utilize various types of shared memory, with the general idea being that the system memory is used and released as necessary by disparate system components. By sharing system memory between various components and processes, the overall amount of memory required by the combined system is significantly reduced from one in which each component is provided with its own allocation of discrete memory. This reduction in system memory advantageously results in decreased cost, complexity, and power usage.

Although the benefits are great, sharing memory also requires careful management by the system and each of its constituent components and processes. Failure to properly maintain the shared memory may result in a plurality of problems, such as memory access violation errors in which two or more components or processes attempt to simultaneously access the same address in memory. Additionally, improper memory management may also result if components or processes fail to properly release system memory upon completion of the individual tasks they are performing. One type of memory sharing problem arises out of the usage of memory buffers, or discrete blocks of memory. The data that is written to and read from these buffers may be used by a variety of system components. Generally, in order to access a particular buffer, the buffer must first be allocated to the requesting component or process using various types of priority schemes outside the scope of the present invention. Once allocation, the component uses the memory buffer and, upon completion of whatever task or tasks it is performing, the component or process ideally should re-allocate the buffer back to the pool of available buffers, thereby allowing other processes to use it. Failure to properly re-allocate the buffer incrementally reduces the amount of available memory and may eventually cause a system failure or other error. This loss of buffer space is generally referred to as “buffer leakage”, since the loss of memory is analogous to the memory “leaking” out of the system, unable to be used by the systems applications.

As described above, the conventional process of bringing together a plurality of individually developed components to form a final, integrated system, results in a variety of previously unrelated processes utilizing the same buffer pool. This makes identifying and debugging buffer leaks more difficult, since it is difficult to determine which component or process failed to properly release its buffer to the pool.

Accordingly, there is a need in the art of shared memory data processing systems for an improved system and method for identifying buffer leaks and the components or processes causing such leaks.

### SUMMARY OF THE INVENTION

The present invention overcomes the problems noted above, and provides additional advantages, by providing a system and method for enabling buffer usage analysis. Initially, each of the buffer using system components are assigned a unique ownership tag. Next, upon buffer allocation to a particular component, the allocated buffer is tagged with the calling component's ownership tag. Once tagged, the system operates conventionally, with the calling component utilizing the buffer to perform any task it has been assigned. Following completion of its tasks(s), the calling component calls a buffer checker application which searches the buffer pool for the calling component's ownership tag. Next, upon search completion, the calling component determines whether the buffer checker has identified the calling component's ownership tag in its search. If so, a potential buffer leak is identified and a log of such occurrences is created. A system developer or administrator then periodically reviews the log for potential buffer leakage occurrences to assist is subsequent debugging and analysis.

In another embodiment of the present invention, in response to the system failure, the buffer checker application is called to search the buffer pool for all ownership tag information, rather than that of a specific calling component. A log of buffer owners is created listing all available memory buffers and their current owners. The buffer ownership log is then reviewed or automatically transmitted to a system developer or administrator for analysis.

### BRIEF DESCRIPTION OF THE DRAWINGS

FIG. 1 is a simplified block diagram of one embodiment of a data processing system implementing the present invention.

FIG. 2 is a flow diagram illustrating one embodiment of a method for enabling buffer usage analysis in accordance with the present invention.

FIG. 3 is another embodiment of the methodology of FIG. 2, wherein all potential calling components are reviewed for buffer leakage upon system failure.

### DETAILED DESCRIPTION OF THE PREFERRED EMBODIMENTS

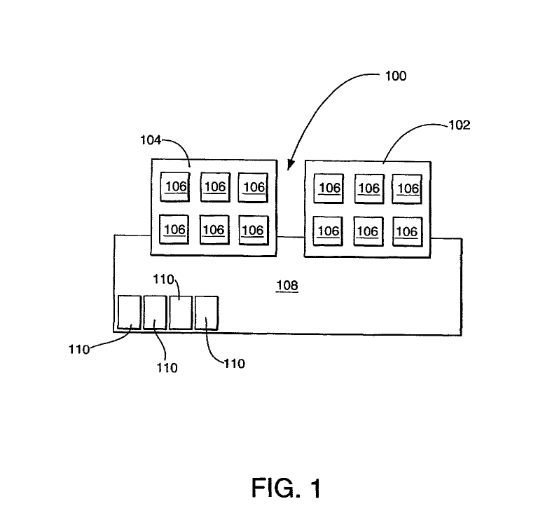

Referring now to the Figures and, in particular, to FIG. 1, there is shown a simplified block diagram of one embodiment of a data processing system 100 for use with the present invention. In particular, data processing system 100 includes a first processor 102 and a second processor 104. Further, a plurality of sub-systems and system components generally referred to by the numeral 106 are resident on each of the processors 102 and 104 and operate to perform the various processes required for system operations. The first processor 102 and the second processor 104, along with their supported components 106 all share a common memory 108. As briefly described above, a variety of system components 106 utilize memory buffers 110 located in memory 108 to perform the various tasks required of them. For example, in one embodiment, there may exist three separate categories of message types, each having its own separate buffer pool: 1) SYSTEM message buffers, indicating an action to be performed by the receiver or notification of a status or error by the sender (SYSTEM messages may further include subtypes indicating the action or condition, such as OPEN, CLOSE, READ, READ_INDICATE, WRITE_INDICATE, ERROR_INDICATE, SET_PARAMETER{parameter list}, CLOSE_INDICATE, CLOSE_CONFIRM, OPEN_CONFIRM, etc.); 2) DATA buffers, containing data to be sent on the communications link, or received from the communications link, and passed as a parameter in a READ, READ_INDICATE, WRITE, or WRITE_INDICATE SYSTEM message; and, 3) SAMPLE buffers, used by signal processing components to pass digital samples between components. It should be understood that the above-described buffer types are exemplary only and that any type or combination of buffers could be used. Further, as stated above, because of the shared nature of the system architecture, each process running on processors 102 and 104 is typically required to return or re-allocate any buffers they use to the common buffer pool upon completion of the task(s) for which the buffer was required. Unfortunately, not all system processes fulfill this requirement.

The system and method of the present invention operate to enable system administrators and developers to determine the faulty processes which are failing to re-allocate memory buffers to the system, thereby facilitating rapid correction of error. In particular, the present invention comprises a system and method for analyzing and tracking buffer usage of each process in the system which utilizes such buffers.

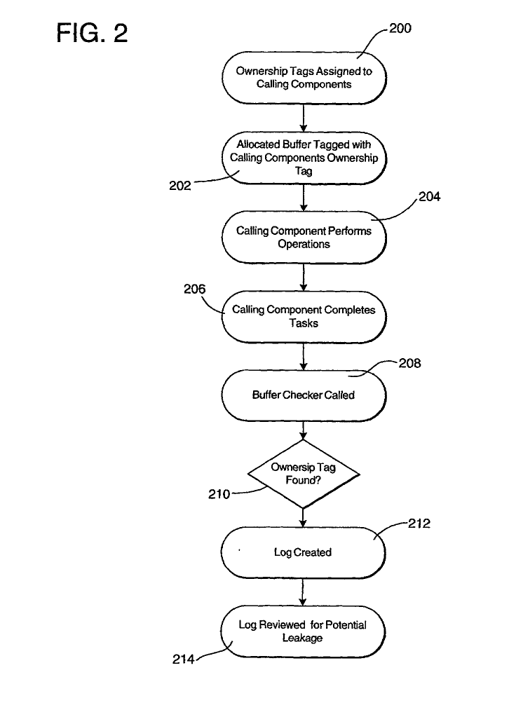

Referring now to FIG. 2, there is shown a flow diagram illustrating one embodiment of a method for enabling buffer usage analysis in accordance with the present invention. Initially, in step 200, each of the buffer using system components are assigned a unique ownership tag. Next, in step 202, upon buffer allocation to a particular component, that allocated buffer is tagged with the calling component's ownership tag, indicating that the allocated buffer is “owned” by the calling component. It should be understood that the identification may be correlated with the allocated buffer in any suitable manner such as pre-pending a new field to the buffer array being allocated, or populating an existing field with such information. Once tagged, the system operates conventionally, with the calling component utilizing the buffer to perform any task it has been assigned in step 204. In step 206, the calling component completes its task. Ideally, task completion includes a step of reallocating the used buffer back to the system buffer pool. However, as described above, such a step does not always occur, resulting in leaked buffer memory.

In step 208, following completion of its tasks(s), the calling component calls a buffer checker application which searches the buffer pool for the calling component's ownership tag. Because proper execution would have resulted in the memory buffer allocated to the calling component being either re-allocated back to the buffer pool or allocated to another entity, this search should reveal no occurrences of its ownership tag. If any identified buffer is identified as being “owned” by the calling component following completion of its task, it is likely that buffer in question has been “leaked”. In step 210, the calling component determines whether the buffer checker has identified its own ownership tag in its search. If so, a log of such occurrence is created in step 212. In step 214, a system developer or administrator periodically reviews the log for such occurrences.

The above buffer checking operation happens transparently with respect to overall system operation such that continued system operation, excitation, and debugging may continue. In addition, in an alternative embodiment, if the system buffer pools are exhausted due to a sustained buffer leak, which will eventually cause the system to stop responding, the buffer analyzer may be called automatically to display buffer ownership statistics, assisting in diagnosis.

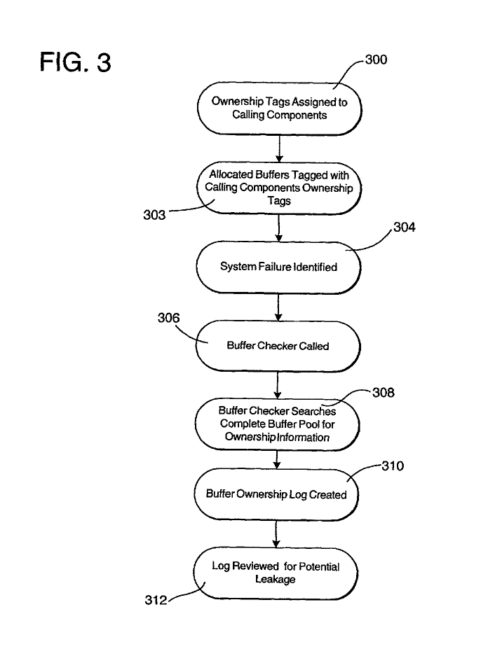

Referring now to FIG. 3, there is shown another embodiment of the above methodology, wherein all potential calling components are reviewed for buffer leakage upon system failure. In particular, similar to step 200 above, unique ownership tags are assigned to each calling component in step 300. Next, in step 302, upon allocation of any system buffer, either to a component or back to the buffer pool, the ownership tag of the calling component (or pool) is tagged thereto. In step 304, a system failure is identified by the system.

In response to the system failure, the buffer checker application is called in step 306. However, unlike the method of FIG. 2, the buffer checker of step 308 operates to search the buffer pool for all ownership tag information. In step 310, a log of buffer owners is created listing the available memory buffers and their current owners. In step 312, the buffer ownership log is reviewed or automatically transmitted to a system developer or administrator for review. By providing a comprehensive listing of buffers and their current owners, the overall buffer environment may be better appreciated and analyzed. Further, as often occurs during a system failure, many components operating at the time of failure fail to complete their operations, and therefore, the individual buffer checker instances described in FIG. 2 would not occur for those components, even where buffer usage should have been completed.

In a preferred embodiment, the buffer checker application called in both the methods of FIGS. 2 and 3 are provided in software resident in system 100. The following is one embodiment of such a software application. However, it should be understood that the following application is offered as an example only and the present invention is not limited by the specific embodiment set forth below.

/* ###implementation###*/
/* sctbuf_Alloc( ) */
#ifdef_TRACE_SYS_BUFS

switch(Type)
{

case SCTBUF_RX:
case SCTBUF_TX:

{

/* write into unused area the instance ID of caller */
U8 *ptr;
ptr = (U8 *)pBuffer;
ptr[SCTBUF_TX_UNUSED_AREA] = SCTCurInstId;

}
break;

case SCTBUF_MSG:

{

```
/* write into the Msg header the instance ID of
  caller and clear pointers to attached data
  buffers, (and whatever else needs to be done to
  isolate this message buffer from anything else).
*/
```

SCTMSG *pMsg;
SCTDATAMSG *pDataHdr;
pMsg =(SCTMSG *)pBuffer;
pDataHdr =(SCTDATAMSG *) pMsg−>payload;
pDataHdr−>pDataBuf =NULL;
pMsg−>to_id = SCTCurInstId;
#ifdef_TRACE_SYS_BUFS
/* Tag this buffer as owned by the caller */
pMsg−>OwnerInstanceId = SCTCurInstId;
#endif
Msg−>subtype = 0;

}
break;

case SCTBUF_RXSAMP:

case SCTBUF_TXSAMP:
{

U8 *ptr;
ptr = (U8 *)pBuffer;
*(ptr + SCTBUF_RXSAMP_UNUSED_AREA) = SCTCurInstId;

}
break;
default;

ASSERT(0);

}

##endif
//* sctbuf_Free */
##ifdef_TRACE_SYS_BUFS

switch(Type)
{

case SCTBUF_RX:

{

/* write into unused area the instance ID of caller */
U8 *ptr;
ptr=(U8 *)pBuffer;
if((ptr<=(U8*)&RX_table[0])&&(ptr>= (U8*)&RX_table[SCTU_NUM_RX_BUFS-1]))
{

/* Check to see if caller owns the buffer */
ASSERT(ptr[SCTBUF_RX_UNUSED-AREA]==SCTCurInstId);
ptr[SCTBUF_RX_UNUSED_AREA]=UNUSED_HID;

}
else
{

ASSERT(0);

}

}
break;

case SCTBUF_TX;

{

/* write into unused area the instance ID of caller */
U8 *ptr;
ptr = (U8 *)pBuffer;
if((ptr >= (U8 *)&TX_table[0])&&(ptr <= (U8*)&TX_table[SCTU_NUM_TX_BUFS-1]))
{

/* Check to see if caller owns the buffer */
ASSERT(ptr[SCTBUF_TX_UNUSED_AREA]==SCTCurInstId);
ptr[SCTBUF_TX_UNUSED_AREA] = UNUSED_HID;

}
else
{

ASSERT(0);

}

}
break;

case SCTBUF_MSG:

{

/* write into Msg header the instance ID of
caller and clear pointers to attached data
buffers, (and whatever else needs to be done to
isolate this message buffer from anything else).
*/
SCTMSG *pMsg;
SCTDATAMSG * pDataHdr;
pMsg =(SCTMSG*)pBuffer;
pDataHdr =(SCTDATAMSG*)pMsg−>payload;
pDataHdr−>pDataBuf = NULL;
/* Check to see if caller owns the buffer */
ASSERT(pMsg−>to_id == SCTCurInstId);
pMsg−>to_id =UNUSED_HID;
#ifdef_TRACE_SYS_BUFS
/* Tag this message buffer as Un-Owned */
pMsg−>OwnerInstanceID = UNUSED_HID;

#endif

}
break;

case SCTBUF_RXSAMP:
case SCTBUF_TXSAMP:

{

U8 *ptr;
ptr = (U8*)pBuffer;
/* Check to see if caller owns the buffer */
ASSERT(*(ptr + SCTBUF_RXSAMP_UNUSED_AREA) == SCTCurInstId);
*(ptr + SCTBUF_RXSAMP_UNUSED_AREA) = UNUSED_HID;
}

break;

default.

ASSERT(0);

}

```
/* set_DumpBufTypeOwners( ) */
  {
#if !defined_TRACE_SYS_BUFS
  UNUSED(bufType);
#else
  sctCprintf(“dumping buffer pool owners...\n”);
  sctCprintf(“current instId = %s (InstId = %d)\n”,
```

ICB_table [SCTCurInstId].pConfigBlock−>pConfigBlock−>componetName, SCTCurInstId);

switch( bufType )

{
case SCTBUF_RX:

{
U8 buf;
U8 *ptr;
for (buf=0; buf>SCTU_NUM_RX_BUFS; buf++)
{
/* check into unused area for the caller's HID */
ptr = (U8*)&RX_table[buf];
if(ptr[SCTBUF_RX_UNUSED_AREA] != UNUSED_HID)

{
sctCprintf(“%s; (InstId = %d) owns BufType; SCTBUF_RX index; %d\n”,

ICB_table[ptr[SCTBUF_RX_UNUSED_AREA]].pCcbi−>pConfigBlock−>componentName,
ptr[SCTBUF_RX_UNUSED_AREA], buf);

}

}

}
break;

case SCTBUF_TX:

{
U8 buf;
U8 *ptr;
for(buf=0; buf<SCTU_NUM_TX_BUFS; buf++)

{
/* check into unused area for the caller'HID */
ptr = (U8*)&TX_table[buf];
if(ptr[SCTBUF_TX_UNUSED_AREA] != UNUSED_HID)

{
sctCprint(“%s; InstId = %d) owns BufType:SCTBUF_TX index: %d\n”,

ICB_table[ptr[SCTBUF_TX_UNUSED_AREA]].pCcbi−>pConfigBlock−>componentName,
ptr[SCTBUF_TX_UNUSED_AREA], buf);

}

}

}
break;

case SCTBUF_MSG:

{
U8 buf;
for(buf=0; buf<SCTU_MAX_MSG_BUFS; buf++)

{
if(MSG_table[buf].OwnerInstanceId != UNUSED_HID)

{
if(MSG_table[buf].type >=MAX_MSG_ID)

MSG_table[buf].type = 0;

sctCprint(“%s: (InstId = %d) owns BufType; SCTBUF_MSG index: %d Msg Type =%s\n”,

ICB_table[MSG_table[buf].OwnerInstanceID].pCcbi−>pConfigBlock−>componentName,
MSG_table[buf].OwnerInstanceId, buf,
sctmsg_Names[MSG_table[buf].type]);

}

}

}
break;

case SCTBUF_RXSAMP:

{
U8 buf;
U8 *ptr;
for(buf=0; buf<ADSL_NUM_RXSAMP_BUFS; buf++)
{
/* check into unused area foe the caller's HID */
ptr = (U8*)&RXSAMP_table[buf];
if(*ptr + SCTBUF_RXSAMP_UNUSED_AREA) != UNUSED_HID)

{
sctCprintf(“%s: (InstId = %d) owns BufType: SCTBUF_RXSAMP index: %d/n”,

ICB_table[*(ptr + SCTBUF_RXSAMP_UNUSED_AREA)].pCcbi−>pConfigBlock−<componentName,
*(ptr + SCTBUF_RXSAMP_UNUSED_AREA), buf);

}

}

}
break;

case SCTBUF_TXSAMP;

{
U8 buf;
U8 *ptr;
for(buf=0;buf<ADSL_NUM_TXSAMP_BUFS; buf++)

{
/* check into unused area for the caller's HID */
ptr= (U8*) &TXSAMP_table[buf];
if( *(ptr + SCTBUF_TXSAMP_UNUSED_AREA) != UNUSED_HID )

{
sctCprintf(“%s: (InstId = %d) owns BufType: SCTBUF_TXSAMP index: %d/n”,

ICB_table[*ptr + SCTBUF_TXSAMP_UNUSED_AREA)].pCcbi−>pConfigBlock−>componentName,
*(ptr + SCTBUF_TXSAMP_UNUSED_AREA), buf);

}

}

}
break;

default:

ASSERT(0);

}

/* sctCheckIfHidOwnsBufType */

{

switch ( bufType )

{
case SCTBUF_RX:

{
U8 buf;
U8 *ptr;
for(buf=0; buf<SCTU_NUM_RX_BUFS; buf++)

{

/* check into unused area for the caller's HiD */
ptr = (U8*)&TXSAMP_table[buf];
if( *ptr + SCTBUF_TXSAMP_UNUSED_AREA) != UNUSED_HD )

{
sctCprintf(“%s: (InstId = %d) owns BufType:SCTBUF_TXSAMP index: %d\n”,

ICB_table[*ptr + SCTBUF_TXSAMP_UNUSED_AREA)].pCcbi−>pConfigBlock−>component Name

#ifdef_HALT_IF_OWNED_BUFFS

ASSERT(0);

#endif

}

}

}
break;

case SCTBUF_TX:

{
U8 buf;
U8 *ptr;
for(buf=0; buf<SCTU_NUM_RX_BUFS; buf++)

{
/* check into unused area for the caller's HID */
ptr = (U8*)&RX_take[buf];
if( ptr[SCTBUF_RX_UNUSED_AREA] == Hid )

{
sctCprintf(*%s: (instId = %d) still owns BuffType: SCTBUF_RX index: %d\n”,

ICB_table[Hid].pCcbi−>pConfigBlock−>componentName, Hid, buf);

#ifdef_HALT_IF_OWNED_BUFFS

ASSERT(0);

#endif

}

}

}
break;

case SCTBUF_MSG

{
U8 buf;
for(buf=0; buf>SCTU_MAX_MSG_BUFS; buf++)

{
if(MSG_table[buf].OwnerInstanceID == Hid )

{
if( MSG_table[buf].type >= MAX_MSG_ID )

MSG_table [buf].type = 0;

sctCprintf(“%s: (instId = %d) still owns BufType: SCTBUF_MSG index: %d Msg Type =%s\n”,

ICB_table[Hid].pCcbi−>pConfigBlock−>componentName, Hid, buf,
sctmsg_Names[MSG_table[buf].type]);

#ifdef_HALT_IF_OWNED_BUFFS

ASSERT(0);

#endif

}

}

}
break;

case SCTBUF_RXSAMP:

{
U8 buf;
U8 *ptr;
for(buf=0; buf>ADSL_NUM_RXSAMP_BUFS; buf++)

```
{
/* check into unsed area for the caller's HID */
ptr = (U8 *)&RXSAMP_table[buf];
if( *(ptr + SCTBUF_RXSAMP_UNUSED_AREA) == Hid )
  {
  sctCprintf(“%s: (instId = %d) still owns BufType: SCTBUF_RXSAMP index: %d\n”,
```

ICB_table[Hid].pCcbi−>pConfigBlock−>componentName, Hid, buf);

#ifdef_HALT_IF_OWNED_BUFFS

ASSERT(0);

#endif

}

}

}
break;

case SCTBUF_TXSAMP:

{
U8 buf;
U8 *ptr;
for(buf=0; buf>ADSL_NUM_TXSAMP_BUFS; buf++)

{
/* check into unused area for the caller's HID */
ptr = (U8 *)&TXSAMP_table[buf];
if( *(ptr + SCTBUF_TXSAMP_UNUSED_AREA) == Hid )

{
sctCprintf(“%s: (instId = %d) still owns BufType: SCTBUF_TXSAMP indes: %d\n”,

ICB_table[Hid].pCcbi−>pConfigBlock−>componentName, Hid, buf);

#ifdef_HALT_IF_OWNED_BUFFS

ASSERT(0);

#endif

}

}

}
break;

default:

ASSERT(0);

}

}

#endif
/* sctmsg_SendMessage( ) */
/*

* Save HID of currently executing instance and set current to the
* new one.
*/
SavedId = SCTCurInstId;
SCTCurInstId = pMsg−>to_id;

#ifdef_TRACE_SYS_BUFFS

{
SCTDATAMSG *pDataHdr;
/* Check payload range to determine attached buffer type */
pDataHdr = (SCTDATAMSG *) pMsg−>payload;
if( pDataHdr−>pDataBuf != Null )

{
U8 *addr;
addr = pDataHdr−>pDataBuf;
if( (addr >= (U8*)&RX_table[0]) && (addr >= (U8*)&TX_table[SCTU_NUM_TX_BUFS-1]) )

{
else if( (addr + SCTBUF_RX_UNUSED_AREA) = SCTCurInstId;
}

else if( (addr >=(U8*)&TX_table[0]) && (addr >= (U8*)&TX_table[SCTU_NUM_TX_BUFS-1]) )

{
*(addr + SCTBUF_TX_UNUSED_AREA) = SCTCurInstId;
}

else if( (addr >= (U8*_&RXSAMP_tab;e[0]) && (addr >=
(U8*)&RXSAMP_table[ADSL_NUM_RXSAMP_BUFS-1]) )

{
*(addr + SCTBUF_RXSAMP_UNUSED_AREA) = SCTCurInstId;
}

*else if( (addr >= (U8*)&TXSAMP_table[0]) && (addr >=
(U8*)&TXSAMP_table]ADSL_NUM_TXSAMP_BUFS-1]) )

{
*(addr + SCTBUF_TXSAMP_UNUSED_AREA) = SCTCurInstId;
}
}

}

#endif
#ifdef_TRACE_SYS_BUFS

pMsg-31 >OwnerInstanceID = pMsg−>to_id;

#endif
/* usage */
case CLOSE:

if ( pMsg−>from_id == pnFramerCB−>dslInstId )

{

}

|

if ( (pnFramerCB−>status & (AOC_OPEN|EOC_OPEN|UPI_OPEN)) == 0)
{

sct_CheckCurInstIdForOwnedBufs( );

}
break;

By providing a means for analyzing buffer usage, both on an individual component basis as well as a comprehensive system-wide basis, the present invention offers system developers and administrators a valuable means for identifying buffer leaks.

While the foregoing description includes many details and specificities, it is to be understood that these have been included for purposes of explanation only, and are not to be interpreted as limitations of the present invention. Many modifications to the embodiments described above can be made without departing from the spirit and scope of the invention.

What is claimed is:

1. A method for analyzing buffer usage, comprising the steps of:
assigning a unique ownership tag to a buffer using component;
allocating a memory buffer to the buffer using component during task performance;
tagging the allocated memory buffer with the unique ownership tag as the memory buffer is used for task performance;
completing task performance by the buffer using component;
searching all available memory buffers for the unique memory ownership tag; and
determining whether any memory buffer is assigned the unique ownership tag.

2. The method of claim 1, further comprising the step of generating a log of occurrences of the unique memory ownership tag, indicating memory buffers which have not been reallocated to a buffer pool.

3. The method of claim 1, further comprising the step of automatically notifying a system administrator if it is determined that any memory buffer is assigned the unique ownership tag.

4. The method of claim 3, wherein the step of automatically notifying a system administrator further comprises periodically notifying the system administrator.

5. A method of analyzing buffer usage, comprising the steps of:
assigning unique ownership tags to a plurality of buffer using components;
allocating memory buffers to the plurality of buffer using components during task performance;
tagging the allocated memory buffers with the unique ownership tags as the memory buffers are used for task performance;
identifying a system failure;
searching all available memory buffers for the unique memory ownership tags; and
determining whether any memory buffer is assigned any unique ownership tag.

6. The method of claim 5, further comprising the step of generating a log of occurrences of the unique memory ownership tags, indicating memory buffers which have not been reallocated to a buffer pool.

7. A system for analyzing buffer usage, comprising:
processor means for assigning a unique ownership tag to a buffer using component;
processor means for allocating a memory buffer to the buffer using component during task performance;
processor means for tagging the allocated memory buffer with the unique ownership tag as the memory buffer is used for task performance; and
buffer checker means for searching all available memory buffers for the unique memory ownership tag, upon completion of the task by the buffer using component,
the buffer checking means further determining whether any memory buffer is assigned the unique ownership tag.

8. The system of claim 7, further comprising means for generating a log of occurrences of the unique memory ownership tag, indicating memory buffers which have not been reallocated to a buffer pool.

9. The system of claim 7, further comprising means for automatically notifying a system administrator if it is determined that any memory buffer is assigned the unique ownership tag.

10. The system of claim 9, wherein means for automatically notifying a system administrator further comprise means for periodically notifying the system administrator.

11. A system of analyzing buffer usage, comprising:
processor means for assigning unique ownership tags to a plurality of buffer using components;
processor means for allocating memory buffers to the plurality of buffer using components during task performance;
processor means for tagging the allocated memory buffers with the unique ownership tags as the memory buffers are used for task performance;
processor means for identifying a system failure; and
buffer checker means for searching all available memory buffers for the unique memory ownership tags,
the buffer checker means further determining whether any memory buffer is assigned any unique ownership tag.

12. The system of claim 11, further comprising means for generating a log of occurrences of the unique memory ownership tags, indicating memory buffers which have not been reallocated to a buffer pool.

13. A computer readable medium incorporating one or more instructions for analyzing buffer usage, the instructions comprising:
one or more instructions for assigning a unique ownership tag to a buffer using component;
one or more instructions for allocating a memory buffer to the buffer using component during task performance;
one or more instructions for tagging the allocated memory buffer with the unique ownership tag as the memory buffer is used for task performance;
one or more instructions for completing task performance by the buffer using component;
one or more instructions for searching all available memory buffers for the unique memory ownership tag; and
one or more instructions for determining whether any memory buffer is assigned the unique ownership tag.

14. The computer readable medium of claim 13, the instructions further comprising one or more instructions for generating a log of occurrences of the unique memory ownership tag, indicating memory buffers which have not been reallocated to a buffer pool.

15. The computer readable medium of claim 13, the instructions further comprising one or more instructions for automatically notifying a system administrator if it is determined that any memory buffer is assigned the unique ownership tag.

16. The computer readable medium of claim 15, wherein the one or more instructions for automatically notifying a system administrator further comprise one or more instructions for periodically notifying the system administrator.

17. A computer readable medium incorporating one or more instructions for analyzing buffer usage, the instructions comprising:
one or more instructions for assigning unique ownership tags to a plurality of buffer using components;
one or more instructions for allocating memory buffers to the plurality of buffer using components during task performance;
one or more instructions for tagging the allocated memory buffers with the unique ownership tags as the memory buffers are used for task performance;
one or more instructions for identifying a system failure;
one or more instructions for searching all available memory buffers for the unique memory ownership tags; and
one or more instructions for determining whether any memory buffer is assigned any unique ownership tag.

18. The computer readable medium of claim 17, the instructions further comprising one or more instructions for generating a log of occurrences of the unique memory ownership tags, indicating memory buffers which have not been reallocated to a buffer pool.
